(19) United States
(12) Patent Application Publication
(10) Pub. No.: US 2023/0187523 A1
(43) Pub. Date: Jun. 15, 2023

(54) HYBRID GATE FIELD EFFECT TRANSISTOR, METHOD FOR PREPARING HYBRID GATE FIELD EFFECT TRANSISTOR, AND SWITCH CIRCUIT

(71) Applicant: Huawei Technologies Co., Ltd., Shenzhen (CN)

(72) Inventors: Ruihong LUO, Dongguan (CN); Boning HUANG, Dongguan (CN); Hui SUN, Shenzhen (CN); Qimeng JIANG, Shenzhen (CN); Qilong BAO, Dongguan (CN); Zhibin CHEN, Dongguan (CN)

(21) Appl. No.: 18/166,391

(22) Filed: Feb. 8, 2023

Related U.S. Application Data
(63) Continuation of application No. PCT/CN2021/110379, filed on Aug. 3, 2021.

(30) Foreign Application Priority Data
Aug. 10, 2020 (CN) 202010795268.4

(51) Int. Cl. H01L 29/47; H01L 23/31; H01L 29/20; H01L 29/205; H01L 29/778; H01L 29/40; H01L 29/66

(52) U.S. Cl. CPC H01L 29/475; H01L 23/3171; H01L 29/205; H01L 29/401; H01L 29/2003; H01L 29/7786; H01L 29/66462

(57) ABSTRACT

This application provides a hybrid gate field effect transistor, a method for preparing the hybrid gate field effect transistor, and a switch circuit. The hybrid gate field effect transistor includes a channel layer, and a source, a drain, and a gate structure disposed on the channel layer. The gate structure is a hybrid gate structure prepared from two materials. The gate structure includes a first structural layer and a second structural layer. The second structural layer wraps the first structural layer. The first structural layer is an N-type gallium nitride layer or an intrinsic gallium nitride layer; and the second structural layer is a P-type gallium nitride layer. The gate metal layer is disposed on one side of the gate structure facing away from the channel layer, and the gate metal layer is in ohmic contact with the first structural layer.

### CROSS-REFERENCE TO RELATED APPLICATIONS

This application is a continuation of International Application No. PCT/CN2021/110379, filed on Aug. 03, 2021, which claims priority to Chinese Patent Application No. 202010795268.4, filed on Aug. 10, 2020. The disclosures of the aforementioned applications are hereby incorporated by reference in their entireties.

### TECHNICAL FIELD

This application relates to the field of communication technologies, and in particular, to a hybrid gate field effect transistor, a method for preparing the hybrid gate field effect transistor, and a switch circuit.

### BACKGROUND

A field effect transistor is widely used in various scenarios as an element of a circuit switch. A field effect transistor with a GaN (gallium nitride)-based material has high mobility and high chemical stability due to the characteristic of the material, and can be used as a higher frequency switch.

The GaN field effect transistor is switched on/off by controlling on/off of two-dimensional electron gas of a channel. GaN field effect transistors are usually divided into two types. One is normally on field effect transistors, also referred to as depletion mode field effect transistors. The other is normally off field effect transistors, also referred to as enhancement mode field effect transistors. However, for the safety of a power consumption system, a switch device is usually required to be normally off. At present, there are several ways to realize the normally off device.

A GaN field effect transistor provided in the conventional technology includes a source, a drain, a gate structure, and a gate metal layer. In use, the gate structure is supplied with power by using the gate metal layer, and the conduction of the source and the drain is controlled by using the gate structure. However, the gate metal layer is usually in Schottky contact with the gate structure, and the Schottky junction may fail due to long-term thermal electron bombardment. This results in low reliability of the GaN field effect transistor.

### SUMMARY

This application provides a hybrid gate field effect transistor, a method for preparing the hybrid gate field effect transistor, and a switch circuit, so as to improve reliability of a hybrid gate field effect transistor.

According to a first aspect, a hybrid gate field effect transistor is provided. The hybrid gate field effect transistor is applied to a switch circuit, is used as a main device of the switch circuit, and is configured to control switch-on and switch-off of the switch circuit. The hybrid gate field effect transistor includes a channel layer, and a source, a drain, and a gate structure that are stacked with the channel layer. The source, the drain, and the gate structure are disposed in a same layer, and the gate structure is located between the source and the drain. In this application, the gate structure is a hybrid gate structure prepared from two materials. In an embodiment, the gate structure includes a first structural layer and a second structural layer. The first structural layer and the second structural layer are disposed in a same layer, and the first structural layer and the second structural layer are separately connected to the channel layer. In addition, the second structural layer wraps the first structural layer when disposed. The first structural layer is located in the middle of the gate structure, and the second structural layer is located on the periphery of the gate structure. In this application, the first structural layer is an N-type gallium nitride layer or an intrinsic gallium nitride layer; and the second structural layer is a P-type gallium nitride layer. The hybrid gate field effect transistor further includes a gate metal layer. The gate metal layer is disposed on one side of the gate structure facing away from the channel layer, and the gate metal layer may be in ohmic contact with the first structural layer. It can be learned from the foregoing description that, in a manner of using the hybrid gate structure as the gate structure, the gate structure is prepared by using two different materials, and the material located in the middle of the hybrid gate may be in ohmic contact with the gate metal layer, to improve reliability of connection between the gate metal layer and the gate structure, thereby improving reliability of the hybrid gate field effect transistor.

In an embodiment, the channel layer includes a gallium nitride layer and an aluminum gallium nitride barrier layer that are stacked; and the source, the drain, and the gate structure are disposed on the aluminum gallium nitride barrier layer. A channel is formed between the gallium nitride layer and the aluminum gallium nitride barrier layer by using the gallium nitride layer and the aluminum gallium nitride barrier layer.

In an embodiment, a substrate, and a buffer layer disposed on the substrate are further included. The gallium nitride layer is formed on the buffer layer. By using the disposed buffer layer, the gallium nitride layer can be carried on the substrate.

In an embodiment, a material of the substrate can be silicon, sapphire, silicon carbide, or a gallium nitride material. The substrate may be prepared by using different materials.

In an embodiment, a passivation layer is further included, and the passivation layer and the aluminum gallium nitride barrier layer are stacked; and the source, the drain, and the gate structure run through the passivation layer, and are exposed outside the passivation layer. A structural layer of the hybrid gate field effect transistor is protected by using the passivation layer.

In an embodiment, the first structural layer is cylindrical, square columnar, or cylindroid. A shape of the first structural layer may be selected to be different.

In an embodiment, there may be at least one first structural layer. For example, there may be one, two, three, or more first structural layers.

In an embodiment, when there are a plurality of first structural layers, the plurality of first structural layers may be arranged in one row, in an array, or in another arrangement manner.

In an embodiment, the gate metal layer is in Schottky contact with the second structural layer. The gate metal layer is connected to the first structural layer and the second structural layer of the gate structure respectively in two different connection manners.

According to a second aspect, a method for preparing a hybrid gate field effect transistor is provided. The method includes the following steps:
forming a first structural layer and a second structural layer on a channel layer, where the first structural layer and the second structural layer are disposed in a same layer, and the second structural layer wraps the first structural layer; and the first structural layer and the second structural layer form a gate structure; and
forming a source and a drain on the channel layer.

It can be learned from the foregoing description that, in a manner of using the hybrid gate structure as the gate structure, the gate structure is prepared by using two different materials, and the material located in the middle of the hybrid gate may be in ohmic contact with the gate metal layer, to improve reliability of connection between the gate metal layer and the gate structure, thereby improving reliability of the hybrid gate field effect transistor.

In an embodiment, the forming a first structural layer and a second structural layer on a channel layer includes: forming an etching layer on the channel layer; etching an annular hole in the etching layer; forming the second structural layer in the annular hole; etching a through hole in the etching layer, where an inner side wall of the second structural layer is a side wall of the through hole; forming the first structural layer in the through hole, where the second structural layer wraps the first structural layer; and etching off a remaining part of the etching layer. The gate structure is formed in an etching manner.

In an embodiment, the forming a first structural layer and a second structural layer on a channel layer includes: forming an etching layer on the channel layer; etching a through hole in the etching layer; forming the first structural layer in the through hole; etching an annular hole in the etching layer, where an outer side wall of the first structural layer is exposed outside the annular hole; and forming the second structural layer in the annular hole, where the second structural layer wraps the first structural layer; and etching off a remaining part of the etching layer. The gate structure is formed in an etching manner.

In an embodiment, the forming a first structural layer and a second structural layer on a channel layer includes: forming, on the channel layer, a material layer with a same material as that of the first structural layer; etching the material layer to form the first structural layer; and forming the second structural layer through ion injection, where the second structural layer wraps the first structural layer. The gate structure is formed in a manner of ion injection.

In an embodiment, the forming a first structural layer and a second structural layer on a channel layer includes: forming, on the channel layer, a material layer with a same material as that of the second structural layer; etching the material layer to form the second structural layer; and forming the first structural layer through ion injection, where the second structural layer wraps the first structural layer. The gate structure is formed in a manner of ion injection.

In an embodiment, the method further includes: forming a buffer layer on a substrate; and forming the channel layer on the buffer layer.

According to a third aspect, a switch circuit is provided. The switch circuit includes a mainboard and the hybrid gate field effect transistor according to any one of the foregoing implementations that is disposed on the mainboard. It can be learned from the foregoing description that, in a manner of using the hybrid gate structure as the gate structure, the gate structure is prepared by using two different materials, and the material located in the middle of the hybrid gate may be in ohmic contact with the gate metal layer, to improve reliability of connection between the gate metal layer and the gate structure, thereby improving reliability of the hybrid gate field effect transistor.

### BRIEF DESCRIPTION OF DRAWINGS

FIG. 1 is a schematic diagram of a structure of a hybrid gate field effect transistor according to an embodiment of this application;

FIG. 2 is a top view of a gate structure of a hybrid gate field effect transistor according to an embodiment of this application;

FIG. 3 is another top view of a gate structure of a hybrid gate field effect transistor according to an embodiment of this application;

FIG. 4 is another top view of a gate structure of a hybrid gate field effect transistor according to an embodiment of this application;

FIG. 5a to FIG. 5g are flowcharts for preparing a hybrid gate field effect transistor according to an embodiment of this application;

FIG. 6a to FIG. 6g are other flowcharts for preparing a hybrid gate field effect transistor according to an embodiment of this application;

FIG. 7a to FIG. 7d are flowcharts for preparing a hybrid gate field effect transistor according to an embodiment of this application; and

FIG. 8a to FIG. 8d are other flowcharts for preparing a hybrid gate field effect transistor according to an embodiment of this application.

### DESCRIPTION OF EMBODIMENTS

The following further describes embodiments of this application with reference to the accompanying drawings.

First, a hybrid gate field effect transistor provided in embodiments of this application is described. A field effect transistor is widely used in various scenarios as an element of a circuit switch. A field effect transistor with a GaN (gallium nitride)-based material has high mobility and high chemical stability due to the characteristic of the material, can be used as a higher frequency switch, and therefore, is widely used in a high-frequency circuit switch.

The GaN field effect transistor is switched on/off by controlling on/off of two-dimensional electron gas of a channel. GaN field effect transistors are usually divided into two types. One is normally on field effect transistors, also referred to as depletion mode field effect transistors. The other is normally off field effect transistors, also referred to as enhancement mode field effect transistors. However, for the safety of a power consumption system, a switch device is usually required to be normally off. At present, there are several ways to realize the normally off device. However, in a current GaN field effect transistor, a gate metal and a gate structure are usually connected in a manner of a Schottky junction, but the Schottky junction may fail due to long-term thermal electron bombardment. This results in low reliability. In view of this, an embodiment of this application provides a hybrid gate field effect transistor used to improve reliability of a field effect transistor. The following describes the hybrid gate field effect transistor in detail with reference to specific accompanying drawings and embodiments.

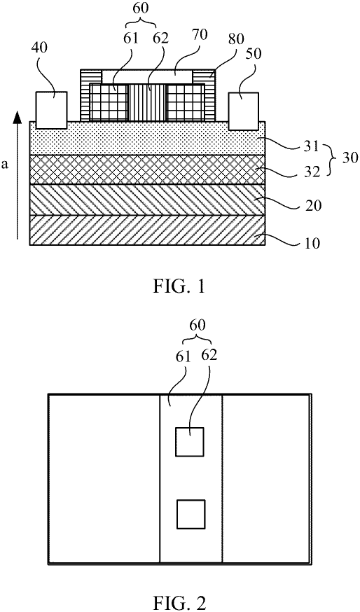

FIG. 1 is a schematic diagram of structural layers of a hybrid gate field effect transistor according to an embodiment of this application. The hybrid gate field effect transistor provided in this embodiment of this application includes a plurality of stacked structural layers. For ease of description, a placement direction of the hybrid gate field effect transistor shown in FIG. 1 is used as a reference direction. The hybrid gate field effect transistor includes a substrate 10, a buffer layer 20, a channel layer 30, a source 40, a drain 50, and a structural layer 60 that are arranged in sequence in a direction a. The following describes the foregoing structural layers in detail with reference to specific accompanying drawings.

The substrate 10 is a basic component of the hybrid gate field effect transistor, and is configured to carry various functional layers of the hybrid gate field effect transistor. When disposed, the substrate 10 may be prepared by using different materials, provided that the substrate 10 has a particular supporting strength. For example, the substrate 10 may be a structural layer prepared by using different materials such as silicon, sapphire, silicon carbide, or gallium nitride. The substrate 10 may be prepared by using different materials.

In an embodiment, a rectangular structural layer may be selected for the substrate 10. However, it should be understood that the shape of the substrate 10 provided in this embodiment of this application is not limited to the rectangular structure, but may be alternatively another different shape, such as an ellipse or a polygon, provided that the substrate 10 has a sufficient area to carry other functional layers of the hybrid gate field effect transistor.

The buffer layer 20 is disposed on the substrate 10, and may be formed on a surface of the substrate 10 by using processes such as chemical vapor deposition and epitaxial growth. The buffer layer 20 is used as an optional structural layer. The buffer layer 20 may be disposed as required during arrangement. For example, when the substrate 10 can directly carry the channel layer 30, the buffer layer 20 may not be disposed, and the channel layer 30 may be directly formed on the substrate 10. When a material of the channel layer 30 conflicts with that of the substrate 10, and the channel layer 30 cannot be directly formed on the substrate 10, the buffer layer 20 is disposed to isolate the substrate 10 from the channel layer 30. In this case, the buffer layer 20 is used as a carrier layer of the channel layer 30. When the buffer layer 20 carries the channel layer 30, on one hand, the buffer layer 20 may be used as a structural layer for carrying the channel, and on the other hand, the buffer layer 20 further has particular elastic deformation performance. The channel layer 30 disposed on a surface of the buffer layer 20 can be protected by using the buffer layer 20, so that reliability and safety of the hybrid gate field effect transistor provided in this embodiment of this application are improved.

In an embodiment, the buffer layer 20 may be a structural layer prepared by using different materials such as gradient aluminum gallium nitride, superlattice, and low-temperature aluminum nitride. When the hybrid gate field effect transistor is prepared, different materials may be selected based on requirements, to prepare the buffer layer 20.

The channel layer 30 is a functional layer of the hybrid gate field effect transistor, and is configured to form two-dimensional electron gas of the hybrid gate field effect transistor. In an embodiment, the channel layer 30 includes a gallium nitride layer 32 and an aluminum gallium nitride barrier layer 31 that are stacked in the direction a. A channel may be formed on a contact surface between the gallium nitride layer 32 and the aluminum gallium nitride barrier layer 31, and the two-dimensional electron gas is located on the contact surface between the gallium nitride layer 32 and the aluminum gallium nitride barrier layer 31.

When the channel layer 30 is disposed, the gallium nitride layer 32 may be disposed on the buffer layer 20, for example, may be directly formed on the buffer layer 20 by using a process such as etching or ion injection. When the substrate 10 can directly carry the channel layer 30, the gallium nitride layer 32 may be directly prepared on the substrate 10 by using a process such as etching or ion injection. The aluminum gallium nitride barrier layer 31 is disposed on a surface of the gallium nitride layer 32 facing away from the substrate 10. During preparation, the aluminum gallium nitride barrier layer 31 may also be prepared by using the foregoing process such as etching or ion injection.

In addition to the foregoing structure, the channel layer 30 may also use another structure. For example, the channel layer 30 includes a three-layer structure, including a gallium nitride layer, an aluminum gallium nitride barrier layer, and an aluminum nitride layer located between the gallium nitride layer and the aluminum gallium nitride barrier layer. A channel may also be formed by using a three-layer structure.

The source-drain layer is a functional layer of the hybrid gate field effect transistor, and includes a source 40, a drain 50, and a gate structural layer 60. As shown in FIG. 1, the source 40, the gate structural layer 60, and the drain 50 are disposed in a same layer on the channel layer 30 and are electrically connected to the channel layer 30. The source 40 and the drain 50 are separately configured to connect to an external circuit, and the gate structural layer 60 is configured to control opening and closing of the channel. When the gate structural layer 60 controls channel conduction, the hybrid gate field effect transistor is in a closed state, and the circuit connected to the source 40 and the drain 50 can be conducted. When the gate structural layer 60 controls channel disconnection, the hybrid gate field effect transistor is in a disconnected state, and the circuit connected to the source 40 and the drain 50 is disconnected.

The gate structural layer 60, the source 40, and the drain 50 are separately connected to the aluminum gallium nitride barrier layer 31, and the source 40 and the drain 50 may communicate with the channel by using the aluminum gallium nitride barrier layer 31. The gate structural layer 60 may be connected to the channel by using the aluminum gallium nitride barrier layer 31 and may deplete electrons located in the channel. When the gate structural layer 60 controls the channel conduction, electrons are located in the channel, and the source 40 and the drain 50 may conduct by using the electrons in the channel. When the gate structural layer 60 controls the channel disconnection, the electrons are depleted by the gate structural layer 60, there are no free electrons in the channel, and the source 40 and the drain 50 are disconnected.

When the source 40, the drain 50, and the gate structural layer 60 are disposed, the gate structural layer 60 is located between the source 40 and the drain 50 and separates the source 40 from the drain 50. It should be understood that, when the gate structural layer 60, the drain 50, and the source 40 are disposed, a gap is spaced between the gate structural layer 60 and the source 40 and the drain 50, to ensure electrical isolation between the gate structural layer 60 and the source 40 and the drain 50.

The gate structural layer 60 provided in this embodiment of this application uses a hybrid gate structure, and the hybrid gate structure is formed of two materials. For example, the gate structural layer 60 includes a first structural layer 62 and a second structural layer 61. The first structural layer 62 and the second structural layer 61 are disposed in a same layer, and the first structural layer 62 and the second structural layer 61 are separately connected to the channel layer 30. In this embodiment of this application, the first structural layer 62 and the second structural layer 61 are prepared by using different materials. The first structural layer 62 is an N-type gallium nitride layer or an intrinsic gallium nitride layer, and the second structural layer 61 is a P-type gallium nitride layer. The hybrid gate structure may be composed of the following materials: P-type gallium nitride + N-type gallium nitride; or P-type gallium nitride + intrinsic gallium nitride. During specific preparation, any combination may be selected based on a requirement, to prepare the hybrid gate structure.

The hybrid gate field effect transistor further includes a gate metal layer 70. The gate metal layer 70 is configured to connect to the gate structural layer 60 and configured to apply a control voltage to the gate structural layer 60 for controlling channel opening and closing.

Still referring to FIG. 1, the gate metal layer 70 is stacked with the gate structural layer 60 and is located on a surface of the gate structural layer 60 facing away from the channel layer 30. For ease of description, the surface of the gate structural layer 60 facing away from the channel layer 30 is referred to as a top surface of the gate structural layer 60. On the top surface of the gate structural layer 60, the first structural layer 62 is exposed outside the second structural layer 61, that is, the top surface of the gate structural layer 60 is composed of a surface of the first structural layer 62 and a surface of the second structural layer 61. When the gate structural layer 60 is connected to the gate metal, the top surface of the gate structural layer 60 is a surface on which the gate structural layer 60 is connected to the gate metal layer 70. When connected to the gate structural layer 60, the gate metal layer 70 is in ohmic contact with at least the first structural layer 62. The gate metal layer 70 may be prepared by using a common conductive metal material such as copper, aluminum, titanium, nickel, chromium, or gold. When the first structural layer 62 uses an N-type gallium nitride layer or an intrinsic gallium nitride layer, the gate metal layer 70 may be directly in ohmic contact with a semiconductor material such as an N-type gallium nitride layer or an intrinsic gallium nitride layer. Forming the ohmic contact between the metal and the semiconductor means that a pure resistance is formed at the contact point, and the smaller the resistance is, the better, so that when the component is operated, most of the voltage is applied to the active region and not to the contact surface. In addition, the ohmic contact does not have long-term thermal electron bombardment, and the reliability is high. By using the ohmic contact between the gate metal layer 70 and the gate structural layer 60, reliability of connection between the gate metal layer 70 and the gate structural layer 60 is improved, and reliability of the hybrid gate field effect transistor is further improved.

The gate metal layer 70 is in ohmic contact with at least the first structural layer 62, including but not limited to the following two specific connection manners:
(1) The gate metal layer 70 is in ohmic contact with only the first structural layer 62. The ohmic contact between the gate metal layer 70 and the first structural layer 62 enables the current of the gate metal layer 70 to be better applied to the first structural layer 62.
(2) The gate metal layer 70 is in ohmic contact with the first structural layer 62, and the gate metal layer 70 is in Schottky contact with the second structural layer 61. The gate metal layer 70 is connected to the first structural layer 62 and the second structural layer 61 of the gate structural layer 60 respectively in two different connection manners. Although the gate metal layer 70 is in separate contact with the first structural layer 62 and the second structural layer 61 in different manners to implement electrical connection, the voltage is still applied to the gate structural layer 60 through the ohmic contact because the resistance of the Schottky contact is high.

The hybrid gate field effect transistor further includes a passivation layer 80, and the passivation layer 80 is configured to protect each functional layer in the hybrid gate field effect transistor. During the arrangement, the passivation layer 80 and the aluminum gallium nitride barrier layer 31 are stacked. It should be understood that, to ensure that the source 40, the drain 50, and the gate structural layer 60 can be connected to the external circuit and the control circuit, when the foregoing structures are disposed, the source 40, the drain 50, and the gate structural layer 60 run through the passivation layer 80 and are exposed outside the passivation layer 80. The exposed parts of the source 40, the drain 50, and the gate structural layer 60 may be used for connection to the external circuit and the control circuit.

In an embodiment, the passivation layer 80 may be prepared by using silicon nitride, aluminum oxide, silicon oxynitride, or other common materials.

It should be understood that, the passivation layer 80 is an optional structural layer of the hybrid gate field effect transistor. When an application environment of the hybrid gate field effect transistor is relatively safe, the passivation layer 80 may not be disposed.

When the first structural layer 62 and the second structural layer 61 are prepared, the first structural layer 62 is located in the middle of the gate structural layer 60, the second structural layer 61 is located on the periphery of the gate structural layer 60, and the second structural layer 61 wraps the first structural layer 62. However, the first structural layer 62 may use different shapes and structures. The following describes specific structural forms of the first structural layer 62 and the second structural layer 61 with reference to the accompanying drawings.

FIG. 2 shows a top view of a gate structural layer. The second structural layer 61 wraps the first structural layer 62, the first structural layer 62 is located in the middle of the gate structural layer 60, and the second structural layer 61 is located on the periphery of the gate structural layer 60. There are two first structural layers 62, and each first structural layer 62 is a rectangular structure. When the two first structural layers 62 are disposed, the two first structural layers 62 are spaced apart, and each first structural layer 62 is surrounded by the second structural layer 61.

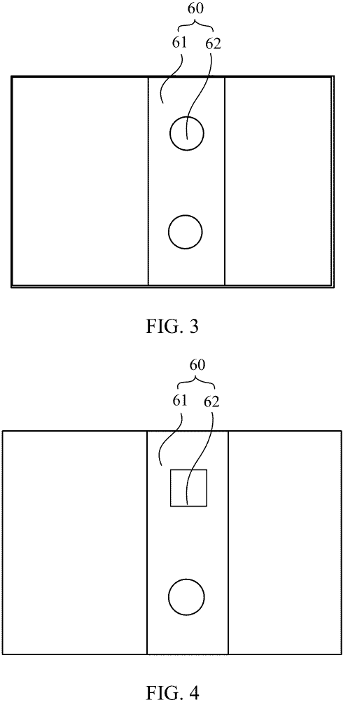

FIG. 3 shows a top view of another gate structural layer. The second structural layer 61 wraps the first structural layer 62, the first structural layer 62 is located in the middle of the gate structural layer 60, and the second structural layer 61 is located on the periphery of the gate structural layer 60. There are two first structural layers 62, and each first structural layer 62 is a circular structure. When the two first structural layers 62 are disposed, the two first structural layers 62 are spaced apart, and each first structural layer 62 is surrounded by the second structural layer 61.

FIG. 4 shows a top view of another gate structural layer 60. The second structural layer 61 wraps the first structural layer 62, the first structural layer 62 is located in the middle of the gate structural layer 60, and the second structural layer 61 is located on the periphery of the gate structural layer 60. There are two first structural layers 62, and one of the first structural layers 62 is circular, and the other one of the first structural layers 62 is rectangular. When the two first structural layers 62 are disposed, the two first structural layers 62 are spaced apart, and each first structural layer 62 is surrounded by the second structural layer 61.

It can be learned from FIG. 2, FIG. 3, and FIG. 4 that the first structural layer 62 provided in this embodiment of this application may use columnar structures with different cross-sectional shapes. FIG. 2, FIG. 3, and FIG. 4 merely illustrate several specific cross-sectional shapes of the first structural layer 62. Other shapes may be alternatively selected for the cross-section of the first structural layer 62 provided in this embodiment of this application. This is not limited herein.

It should be understood that, in this embodiment of this application, a quantity of first structural layers 62 is not limited. In addition to the two first structural layers 62 shown in FIG. 2, FIG. 3, or FIG. 4, different quantities of first structural layers 62, such as one, three, or four, may be used. In an embodiment, a quantity of the first structural layers 62 may be set based on a requirement.

In addition, when a plurality of first structural layers 62 are used, arrangement of the first structural layers 62 is not limited in this embodiment of this application. The first structural layers 62 may be arranged in different arrangement manners such as a single-row arrangement, an array arrangement, a triangular arrangement, an X-shaped arrangement, or a circular arrangement. It is only necessary to ensure that ohmic contact with the gate metal layer 70 is achieved.

In an embodiment, a proportion of the cross-sectional area of the first structural layer 62 to the cross-sectional area of the gate structure 60 is between 5% and 50%. For example, the proportion of the cross-sectional area of the first structural layer 62 to the cross-sectional area of the gate structure 60 may be any proportion of 5%, 10%, 15%, 25%, 30%, 35%, 50%, or the like. It should be understood that, when there are a plurality of first structural layers 62, the cross-sectional area of the first structural layers 62 refers to a sum of the cross-sectional areas of all the first structural layers 62.

It can be learned from the foregoing description that, in the hybrid gate field effect transistor provided in this embodiment of this application, the gate structural layer 60 of the hybrid gate field effect transistor is formed by using the first structural layer 62 and the second structural layer 61. In this way, the gate metal layer 70 can be connected to the gate structural layer 60 in an ohmic contact manner with relatively small resistance, to improve the reliability of the hybrid gate field effect transistor.

To facilitate understanding of the hybrid gate field effect transistor provided in this embodiment of this application, the following describes in detail a method for preparing the hybrid gate field effect transistor with reference to the accompanying drawings. In embodiments of this application, the hybrid gate field effect transistor may be prepared by using different preparation methods, which are described below one by one.

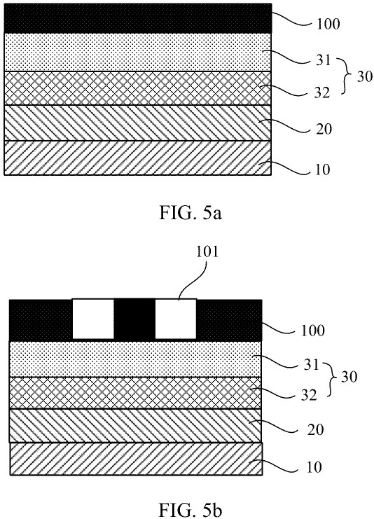

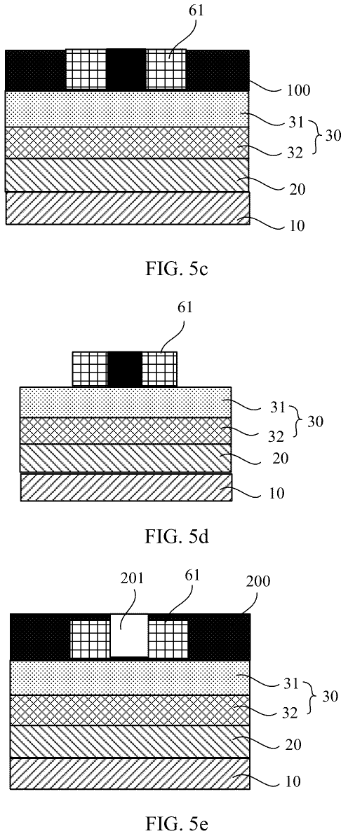

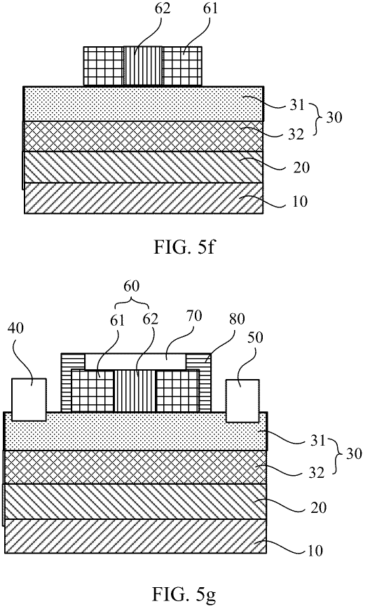

First, FIG. 5a to FIG. 5g show a specific method for preparing a hybrid gate field effect transistor. The method includes the following steps.

Step 001: Form an etching layer on a channel layer.

With reference to FIG. 5a, a substrate 10, a buffer layer 20, a gallium nitride layer 32, and an aluminum gallium nitride barrier layer 31 are formed through stacking by using processes such as epitaxial growth and deposition. When the etching layer 100 is formed on the aluminum gallium nitride barrier layer 31, the etching layer 100 may be directly formed on the aluminum gallium nitride barrier layer 31 in a manner such as coating or deposition. It should be understood that, a thickness of the etching layer 100 should be no less than a thickness of a gate structural layer 60.

Step 002: Etch an annular hole in the etching layer.

With reference to FIG. 5b, the annular hole 101 is formed in the etching layer 100 by using an etching process, and the annular hole 101 runs through the etching layer 100, so that the aluminum gallium nitride barrier layer 31 is exposed in the annular hole 101. A shape of the annular hole 101 matches that of a second structural layer 61, and is used to form the second structural layer 61 in the annular hole 101. In addition, a shape of a physical structure (the residual etching layer 100) in the annular hole 101 matches that of the first structural layer 62, to form the second structural layer 61, leaving space to the first structural layer 62.

Step 003: Form the second structural layer in the annular hole.

With reference to FIG. 5c, the second structural layer 61 is formed in the annular hole 101 in manners such as epitaxial growth and deposition. The formed second structural layer 61 is in contact with the aluminum gallium nitride barrier layer 31.

Step 004: Etch a through hole in the etching layer.

With reference to FIG. 5d, the etching layer 100 on the periphery of the second structural layer 61 is etched off, and only the etching layer located in the second structural layer 61 is retained. With reference to FIG. 5e, a new etching layer 200 is formed. The newly formed etching layer 200 covers the second structural layer 61 and the residual structure of the original etching layer 100. Etching is performed in the newly formed etching layer 200 to form the through hole 201. The through hole 201 is located in the second structural layer 61. In addition, an inner side wall of the second structural layer 61 is used as a side wall of the through hole 201, and a top surface of the aluminum gallium nitride barrier layer 31 is used as a bottom wall of the through hole 201.

Step 005: Form the first structural layer in the through hole.

With reference to FIG. 5f, the first structural layer 62 is formed in the through hole in a manner such as epitaxial growth or deposition. The first structural layer 62 is separately in contact with the second structural layer 61 and the aluminum gallium nitride barrier layer 31.

In addition, when the first structural layer 62 is formed, because the newly formed etching layer covers the second structural layer 61, the formed first structural layer 62 does not cover the second structural layer 61. After preparation, the first structural layer 62 and the second structural layer 61 are disposed in a same layer, and the second structural layer 61 wraps the first structural layer 62.

After the first structural layer 62 is formed, a remaining part of the etching layer is etched off, so that the gate structural layer 60 including the first structural layer 62 and the second structural layer 61 is exposed.

Step 006: Form another layer structure on the channel layer.

With reference to FIG. 5g, a source 40 and a drain 50 are formed on the channel layer 30. In an embodiment, the source 40 and the drain 50 may be formed on the aluminum gallium nitride barrier layer 31 by using a process such as deposition or epitaxial growth.

First, a passivation layer 80 is prepared, the passivation layer 80 is etched to form through holes corresponding to the source 40, the drain 50, and the gate metal layer 70, and the gate metal layer 70, the source 40, and the drain 50 are respectively formed in the through holes. The formed gate metal layer 70 is in ohmic contact with the first structural layer 62 and in Schottky contact with the second structural layer 61.

It can be learned from the foregoing preparation process that, the gate structural layer 60 may be formed by using processes of etching and deposition. In addition, the gate structural layer 60 of the hybrid gate field effect transistor is formed by using the first structural layer 62 and the second structural layer 61, so that the gate metal layer 70 can be connected to the gate structural layer 60 in an ohmic contact manner with small resistance, thereby improving reliability of the hybrid gate field effect transistor.

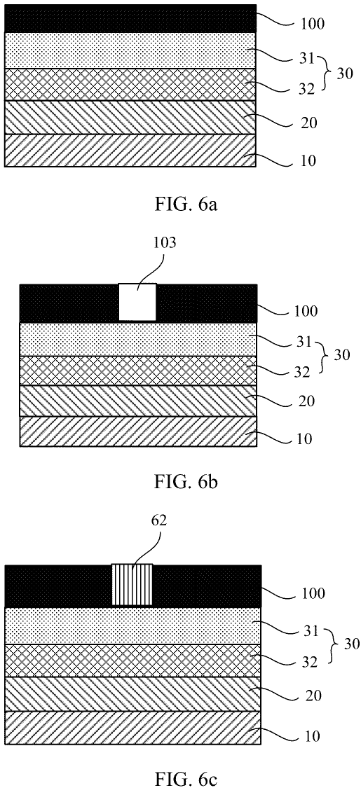

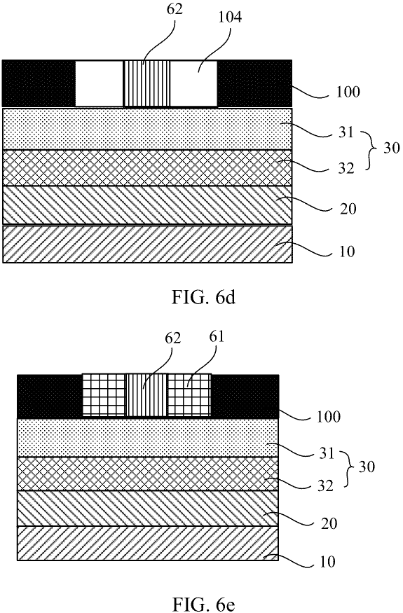

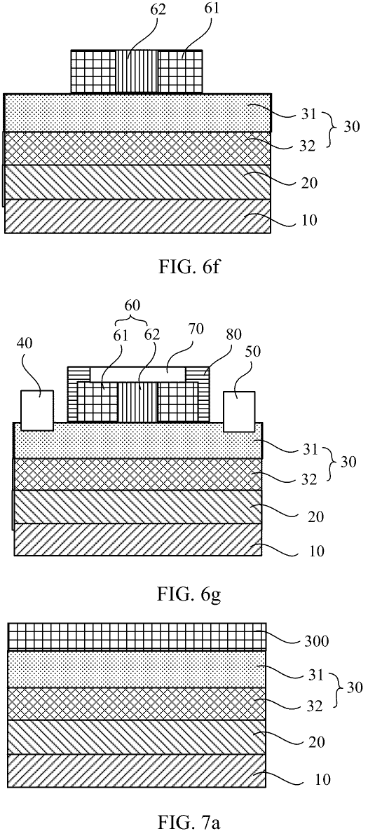

FIG. 6a to FIG. 6g show another specific method for preparing a hybrid gate field effect transistor. The method includes the following steps.

Step 001: Form an etching layer on a channel layer.

With reference to FIG. 6a, a substrate 10, a buffer layer 20, a gallium nitride layer 32, and an aluminum gallium nitride barrier layer 31 are formed through stacking by using processes such as epitaxial growth and deposition. When the etching layer 100 is formed on the aluminum gallium nitride barrier layer 31, the etching layer 100 may be directly formed on the aluminum gallium nitride barrier layer 31 in a manner such as coating or deposition. It should be understood that, a thickness of the etching layer 100 should be no less than a thickness of a gate structural layer 60.

Step 002: Etch a through hole in the etching layer.

With reference to FIG. 6b, the through hole 103 is formed in the etching layer 100 by using an etching process, and the through hole 103 runs through the etching layer 100, so that the aluminum gallium nitride barrier layer 31 is exposed in the through hole 103. A shape of the through hole 103 matches that of a first structural layer 62, and the remaining etching layer is used to form the first structural layer 62 in the through hole 103.

Step 003: Form the first structural layer in the through hole.

With reference to FIG. 6c, the first structural layer 62 is formed in the through hole 103 in manners such as epitaxial growth and deposition. The formed first structural layer 62 is in contact with the aluminum gallium nitride barrier layer 31.

Step 004: Etch an annular hole in the etching layer.

With reference to FIG. 6d, the etching layer 100 on the periphery of the first structural layer 62 is etched off, to form the annular hole 104. An outer side wall of the first structural layer 62 is exposed in the annular hole 104, so that a subsequently prepared second structural layer 61 can be in contact with the first structural layer 62.

Step 005: Form the second structural layer in the annular hole.

With reference to FIG. 6e, the second structural layer 61 is formed in the annular hole 104 in a manner such as epitaxial growth or deposition. The second structural layer 61 is separately in contact with the first structural layer 62 and the aluminum gallium nitride barrier layer 31.

With reference to FIG. 6f, after the second structural layer 61 is formed, a remaining part of the etching layer 100 is etched off, so that the gate structural layer 60 including the first structural layer 62 and the second structural layer 61 is exposed.

Step 006: Form another layer structure on the channel layer.

With reference to FIG. 6g, a source 40 and a drain 50 are formed on the channel layer 30. In an embodiment, the source 40 and the drain 50 may be formed on the aluminum gallium nitride barrier layer 31 by using a process such as deposition or epitaxial growth.

First, a passivation layer 80 is prepared, the passivation layer 80 is etched to form through holes 103 corresponding to the source 40, the drain 50, and the gate metal layer 70, and the gate metal layer 70, the source 40, and the drain 50 are respectively formed in the through holes 103. The formed gate metal layer 70 is in ohmic contact with the first structural layer 62 and in Schottky contact with the second structural layer 61.

It can be learned from the foregoing preparation process that, the gate structural layer 60 may be formed by using processes of etching and deposition. In addition, the gate structural layer 60 of the hybrid gate field effect transistor is formed by using the first structural layer 62 and the second structural layer 61, so that the gate metal layer 70 can be connected to the gate structural layer 60 in an ohmic contact manner with small resistance, thereby improving reliability of the hybrid gate field effect transistor.

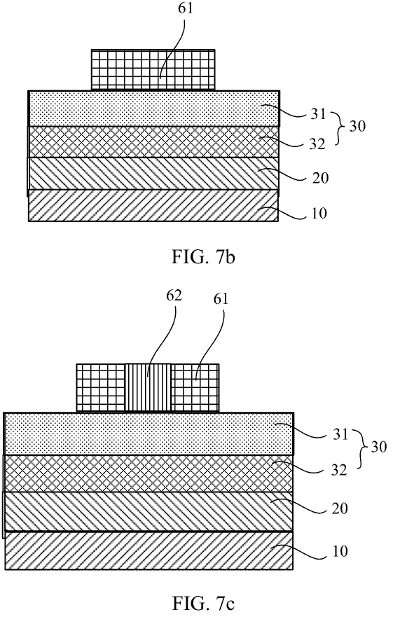

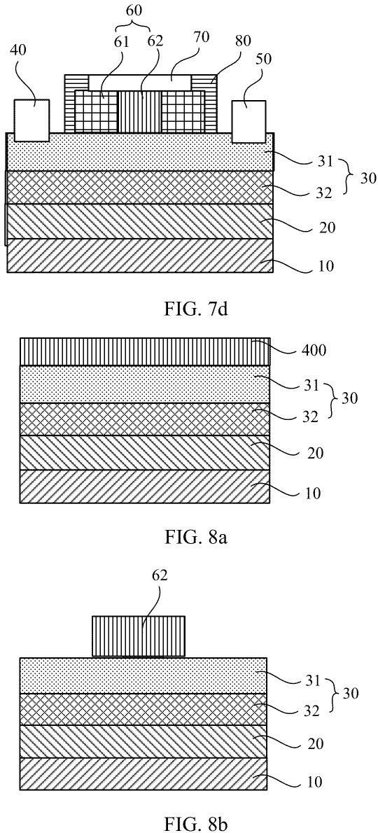

FIG. 7a to FIG. 7d show another specific method for preparing a hybrid gate field effect transistor. The method includes the following steps.

Step 001: Form, on a channel layer, a material layer with a same material as that of a second structural layer.

With reference to FIG. 7a, a substrate 10, a buffer layer 20, a gallium nitride layer 32, and an aluminum gallium nitride barrier layer 31 are formed through stacking by using processes such as epitaxial growth and deposition. When the material layer 300 is formed on the aluminum gallium nitride barrier layer 31, the material layer 300 may be directly formed on the aluminum gallium nitride barrier layer 31 in a manner such as epitaxial growth or deposition. It should be understood that, a thickness of the material layer 300 should be no less than a thickness of a gate structural layer 60.

Step 002: Etch the material layer to form the second structural layer.

With reference to FIG. 7b, the second structural layer 61 with a same size as the gate structural layer 60 is formed by etching the material layer 300.

Step 003: Form the first structural layer through ion injection.

With reference to FIG. 7c, the first structural layer 62 is formed in a manner of injecting counter ions in the second structural layer 61, a part in which counter ions are injected in the second structural layer 61 is used as the first structural layer 62, and a part in which no counter ion is injected is used as the second structural layer 61 of the gate structural layer 60. The second structural layer 61 wraps the first structural layer 62, and for a shape of the formed first structural layer 62, refer to the related description in FIG. 2 to FIG. 4.

Step 004: Form another layer structure on the channel layer.

With reference to FIG. 7d, a source 40 and a drain 50 are formed on the channel layer 30. In an embodiment, the source 40 and the drain 50 may be formed on the aluminum gallium nitride barrier layer 31 by using a process such as deposition or epitaxial growth.

First, a passivation layer 80 is prepared, the passivation layer 80 is etched to form through holes corresponding to the source 40, the drain 50, and the gate metal layer 70, and the gate metal layer 70, the source 40, and the drain 50 are respectively formed in the through holes. The formed gate metal layer 70 is in ohmic contact with the first structural layer 62 and in Schottky contact with the second structural layer 61.

It can be learned from the foregoing preparation process that, the gate structural layer 60 may be formed by using an ion injection process. In addition, the gate structural layer 60 of the hybrid gate field effect transistor is formed by using the first structural layer 62 and the second structural layer 61, so that the gate metal layer 70 can be connected to the gate structural layer 60 in an ohmic contact manner with small resistance, thereby improving reliability of the hybrid gate field effect transistor.

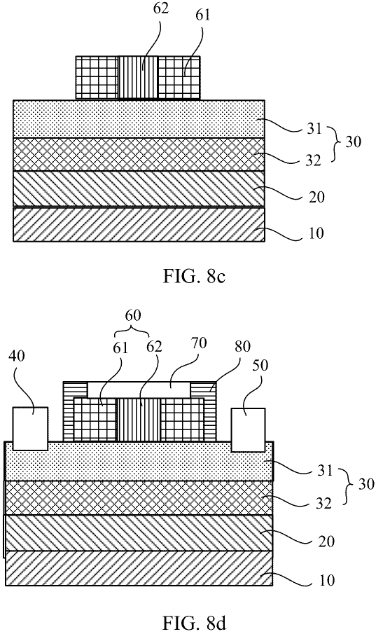

FIG. 8a to FIG. 8d show another specific method for preparing a hybrid gate field effect transistor. The method includes the following steps.

Step 001: Form, on a channel layer, a material layer with a same material as that of a first structural layer.

With reference to FIG. 8a, a substrate 10, a buffer layer 20, a gallium nitride layer 32, and an aluminum gallium nitride barrier layer 31 are formed through stacking by using processes such as epitaxial growth and deposition. When the material layer 400 is formed on the aluminum gallium nitride barrier layer 31, the material layer 400 may be directly formed on the aluminum gallium nitride barrier layer 31 in a manner such as epitaxial growth or deposition. It should be understood that, a thickness of the material layer 400 should be no less than a thickness of a gate structural layer 60.

Step 002: Etch the material layer to form the first structural layer.

With reference to FIG. 8b, the first structural layer 62 with a same size as the gate structural layer 60 is formed by etching the material layer 400.

Step 003: Form the second structural layer through ion injection.

With reference to FIG. 8c, the second structural layer 61 is formed in a manner of injecting counter ions in the first structural layer 62, a part in which counter ions are injected in the first structural layer 62 is used as the second structural layer 61, and a part in which no counter ion is injected is used as the first structural layer 62 of the gate structural layer 60. The second structural layer 61 wraps the first structural layer 62, and for a shape of the formed first structural layer 62, refer to the related description in FIG. 2 to FIG. 4.

Step 004: Form another layer structure on the channel layer.

With reference to FIG. 8d, a source 40 and a drain 50 are formed on the channel layer 30. In an embodiment, the source 40 and the drain 50 may be formed on the aluminum gallium nitride barrier layer 31 by using a process such as deposition or epitaxial growth.

First, a passivation layer 80 is prepared, the passivation layer 80 is etched to form through holes corresponding to the source 40, the drain 50, and the gate metal layer 70, and the gate metal layer 70, the source 40, and the drain 50 are respectively formed in the through holes. The formed gate metal layer 70 is in ohmic contact with the first structural layer 62 and in Schottky contact with the second structural layer 61.

It can be learned from the foregoing preparation process that, the gate structural layer 60 may be formed by using an ion injection process. In addition, the gate structural layer 60 of the hybrid gate field effect transistor is formed by using the first structural layer 62 and the second structural layer 61, so that the gate metal layer 70 can be connected to the gate structural layer 60 in an ohmic contact manner with small resistance, thereby improving reliability of the hybrid gate field effect transistor.

It can be learned from the foregoing description that, the hybrid gate field effect transistor provided in embodiments of this application may be prepared in different manners. In addition, in the formed hybrid gate field effect transistor, the gate structural layer 60 of the hybrid gate field effect transistor is formed by using the first structural layer 62 and the second structural layer 61, so that the gate metal layer 70 can be connected to the gate structural layer 60 in an ohmic contact manner with small resistance, thereby improving reliability of the hybrid gate field effect transistor.

An embodiment of this application further provides a switch circuit. The switch circuit may be a switch circuit in an AC-DC conversion circuit, a high-voltage conversion circuit, or a half bridge rectifier circuit. The switch circuit includes a mainboard and the hybrid gate field effect transistor according to any one of the foregoing implementations that is disposed on the mainboard. It can be learned from the foregoing description that, in a manner of using the hybrid gate structure as the gate structural layer 60, the gate structural layer 60 is prepared by using two different materials, and the material located in the middle of the hybrid gate may be in ohmic contact with the gate metal layer 70, to improve reliability of connection between the gate metal layer 70 and the gate structural layer 60, thereby improving reliability of the hybrid gate field effect transistor.

It is clearly that a person skilled in the art can make various modifications and variations to this application without departing from the spirit and scope of this application. This application is intended to cover these modifications and variations of this application provided that they fall within the scope of protection defined by the following claims and their equivalent technologies.

1. A hybrid gate field effect transistor, comprising:
a channel layer;
a source, a drain, and a gate structure disposed on the channel layer, wherein the source, the drain, and the gate structure are disposed in a same layer, wherein the gate structure comprises a first structural layer and a second structural layer that are disposed in a same layer, and the second structural layer wraps the first structural layer, wherein the first structural layer is an N-type gallium nitride layer or an intrinsic gallium nitride layer, and the second structural layer is a P-type gallium nitride layer; and
a gate metal layer, in ohmic contact with at least the first structural layer.

2. The hybrid gate field effect transistor according to claim 1, wherein
the channel layer comprises a gallium nitride layer and an aluminum gallium nitride barrier layer and
the source, the drain, and the gate structure are disposed on the aluminum gallium nitride barrier layer.

3. The hybrid gate field effect transistor according to claim 2, further comprising;
a substrate and a buffer layer disposed on the substrate, wherein
the gallium nitride layer is on the buffer layer.

4. The hybrid gate field effect transistor according to claim 3, wherein a material of the substrate silicon, sapphire, silicon carbide, or a gallium nitride material.

5. The hybrid gate field effect transistor according to claim 2, further comprising;
a passivation layer, wherein the passivation layer and the aluminum gallium nitride barrier layer are stacked; and
wherein the source, the drain, and the gate structure run through the passivation layer, and are exposed outside of the passivation layer.

6. The hybrid gate field effect transistor according to claim 3, further comprising;
a passivation layer, wherein the passivation layer and the aluminum gallium nitride barrier layer are stacked; and
wherein the source, the drain, and the gate structure run through the passivation layer, and are exposed outside of the passivation layer.

7. The hybrid gate field effect transistor according to claim 4, further comprising;
a passivation layer, wherein the passivation layer and the aluminum gallium nitride barrier layer are stacked; and
wherein the source, the drain, and the gate structure run through the passivation layer, and are exposed outside of the passivation layer.

8. The hybrid gate field effect transistor according to claim 1, wherein the first structural layer is cylindrical, square columnar, or cylindroid.

9. The hybrid gate field effect transistor according to claim 1, wherein the gate metal layer is in Schottky contact with the second structural layer.

10. A method for preparing a hybrid gate field effect transistor, comprising
forming a first structural layer and a second structural layer on a channel layer, wherein the first structural layer and the second structural layer are disposed in a same layer, and the second structural layer wraps the first structural layer, and the first structural layer and the second structural layer form a gate structure; and
forming a source and a drain on the channel layer.

11. The according to claim 10, wherein the-forming the first structural layer and the second structural layer on the channel layer comprises:
forming an etching layer on the channel layer;
etching an annular hole in the etching layer;
forming the second structural layer in the annular hole;
etching a through hole in the etching layer, wherein an inner side wall of the second structural layer is a side wall of the through hole;
forming the first structural layer in the through hole, wherein the second structural layer wraps the first structural layer; and
etching off a remaining part of the etching layer.

12. The method according to claim 10, wherein forming the first structural layer and the second structural layer on the channel layer comprises:
forming an etching layer on the channel layer;
etching a through hole in the etching layer;
forming the first structural layer in the through hole;
etching an annular hole in the etching layer, wherein an outer side wall of the first structural layer is exposed outside the annular hole;
forming the second structural layer in the annular hole, wherein the second structural layer wraps the first structural layer; and
etching off a remaining part of the etching layer.

13. The method according to claim 10, wherein the-forming thea first structural layer and the second structural layer on the channel layer comprises:
forming, on the channel layer, a material layer with a same material as that of the first structural layer;
etching the material layer to form the first structural layer; and
forming the second structural layer through ion injection, wherein the second structural layer wraps the first structural layer.

14. The method according to claim 10, wherein the-forming athe first structural layer and the second structural layer on the channel layer comprises:
forming, on the channel layer, a material layer with a same material as that of the second structural layer;
etching the material layer to form the second structural layer; and
forming the first structural layer through ion injection, wherein the second structural layer wraps the first structural layer.

15. The method according to claim 10, further comprising:
forming a buffer layer on a substrate; and
forming the channel layer on the buffer layer.

16. A switch circuit, comprising a mainboard and a hybrid gate field effect transistor, the hybrid gate field effect transistor comprising:
a channel layer;
a source, a drain, and a gate structure disposed on the channel layer, wherein the source, the drain, and the gate structure are disposed in a same layer, wherein the gate structure comprises a first structural layer and a second structural layer that are disposed in a same layer, and the second structural layer wraps the first structural layer, wherein the first structural layer is an N-type gallium nitride layer or an intrinsic gallium nitride layer, and the second structural layer is a P-type gallium nitride layer; and
a gate metal layer, in ohmic contact with at least the first structural layer.

17. The switch circuit according to claim 16, wherein
the channel layer comprises a gallium nitride layer and an aluminum gallium nitride barrier layer; and
the source, the drain, and the gate structure are disposed on the aluminum gallium nitride barrier layer.

18. The switch circuit according to claim 17, wherein the hybrid gate field effect transistor further comprises:
a substrate and a buffer layer disposed on the substrate, wherein
the gallium nitride layer is on the buffer layer.

19. The switch circuit according to claim 17, wherein the hybrid gate field effect transistor further comprises:
a passivation layer, wherein the passivation layer and the aluminum gallium nitride barrier layer are stacked; and
wherein the source, the drain, and the gate structure run through the passivation layer, and are exposed outside of the passivation layer.

20. The switch circuit according to claim 18, wherein the hybrid gate field effect transistor further comprises:
a passivation layer, wherein the passivation layer and the aluminum gallium nitride barrier layer are stacked; and
wherein the source, the drain, and the gate structure run through the passivation layer, and are exposed outside of the passivation layer.
